(19) United States
(12) Patent Application Publication
(10) Pub. No.: US 2023/0269863 A1
(43) Pub. Date: Aug. 24, 2023

(54) SUPPLY DEVICE AND DETERMINATION DEVICE

(71) Applicant: KYOCERA CORPORATION, Kyoto-shi, Kyoto (JP)

(72) Inventor: Hiromichi YOSHIKAWA, Yokohama-shi, Kanagawa (JP)

(21) Appl. No.: 18/040,152

(22) PCT Filed: Jul. 27, 2021
(86) PCT No.: PCT/JP2021/027790

§ 371 Date: Feb. 1, 2023

(30) Foreign Application Priority Data
Aug. 11, 2020 (JP) 2020-136043

(51) Int. Cl. H05K 1/02; H01P 7/00

(52) U.S. Cl. CPC H05K 1/0237; H01P 7/00

(57) ABSTRACT

A supply device includes a resonator and a supply target line, and the supply target line includes a first signal line, a first reference line, and a second reference line. The first reference line surrounds the first signal line. The second reference line is located away from the first reference line and surrounds the first signal line. The resonator is located between the first reference line and the second reference line and surrounds the first signal line. The resonator includes an open portion forming capacitive connection and includes a second signal line electrically or magnetically connected to the resonator.

### RELATED APPLICATIONS

The present application is a National Phase of International Application Number PCT/JP2021/027790 filed Jul. 27, 2021, which claims the benefit of priority from Japanese Patent Application No. 2020-136043, filed on Aug. 11, 2020.

### TECHNICAL FIELD

The present disclosure relates to a supply device and a determination device.

### BACKGROUND OF INVENTION

A known structure of a filter for suppressing propagation of unnecessary noise in a printed circuit board or a device package substrate is an EBG (Electromagnetic Band Gap) structure. For example, Patent Document 1 discloses a technology that can realize a miniaturizable EBG structure at low cost without using chip components.

### CITATION LIST

### Patent Literature

Patent Document 1: JP 2014-197877 A

### SUMMARY

### Problem to be Solved

The EBG structure applied to a printed circuit board or the like is a two-dimensional structure. When adopting a three-dimensional EBG structure, there is room for improving functions such that electrical power can be supplied to other external devices and determination can be performed for target conductors, for example.

The present disclosure provides a supply device and a determination device that have a novel resonance structure.

### Solution to Problem

In an aspect of the present disclosure, a supply device includes a resonator and a supply target line, wherein the supply target line includes a first signal line, a first reference line, and a second reference line; the first reference line surrounds the first signal line; the second reference line is located away from the first reference line and surrounds the first signal line; the resonator is located between the first reference line and the second reference line and surrounds the first signal line; and the resonator includes an open portion forming capacitive connection and includes a second signal line electrically or magnetically connected to the resonator.

In an aspect of the present disclosure, a determination device includes a resonator, a first reference line, and a second reference line, wherein the first reference line surrounds a target conductor as a determination target; the second reference line is located away from the first reference line and surrounds the target conductor; the resonator is located between the first reference line and the second reference line and surrounds the target conductor; the resonator includes an open portion forming capacitive connection and includes a signal line electrically or magnetically connected to the resonator.

### Advantageous Effect

The present disclosure can provide a supply device and a determination device that have a novel resonance structure.

### BRIEF DESCRIPTION OF THE DRAWINGS

FIG. 1 is a diagram for describing a basic structure of a supply device according to an embodiment.

FIG. 2 is a diagram for describing a configuration example of a supply device according to a first embodiment.

FIG. 3A is a diagram for describing a simulation model of the supply device according to the first embodiment.

FIG. 3B is a diagram for describing a simulation model of the supply device according to the first embodiment.

FIG. 4 is a diagram for describing a state of the magnetic field distribution of the supply device according to the first embodiment.

FIG. 5 is a diagram for describing a state of rotation of the magnetic field of the supply device according to the first embodiment.

FIG. 6A is a graph illustrating a current value of an input signal.

FIG. 6B is a graph illustrating a voltage value of a voltage generated by a vector potential.

FIG. 7 is a diagram for describing a configuration example of a supply device according to a variation of the first embodiment.

FIG. 8 is a diagram for describing a configuration example of a supply device according to a second embodiment.

FIG. 9 is a diagram for describing a configuration example of a supply device according to a third embodiment.

FIG. 10 is a diagram for describing a simulation model of the supply device according to the third embodiment.

FIG. 11 is a diagram for describing a state of the magnetic field distribution of the supply device according to the third embodiment.

Embodiments of the present invention will now be described in detail with reference to the accompanying drawings. Note that the present invention is not limited by the embodiments, and when there are a plurality of embodiments, the present invention includes a combination of the embodiments. In the following embodiments, the same reference numerals are assigned to the same portions and redundant descriptions thereof will be omitted.

In the following description, a three-dimensional orthogonal coordinate system is set, and the positional relationship of parts will be described with reference to the three-dimensional orthogonal coordinate system. A direction parallel to an X axis in the predetermined plane is defined as an X axis direction, a direction parallel to a Y axis orthogonal to the X axis in the predetermined plane is defined as a Y axis direction, and a direction parallel to a Z axis orthogonal to the X and Y axes is defined as a Z axis direction.

### Basic Structure of Supply Device

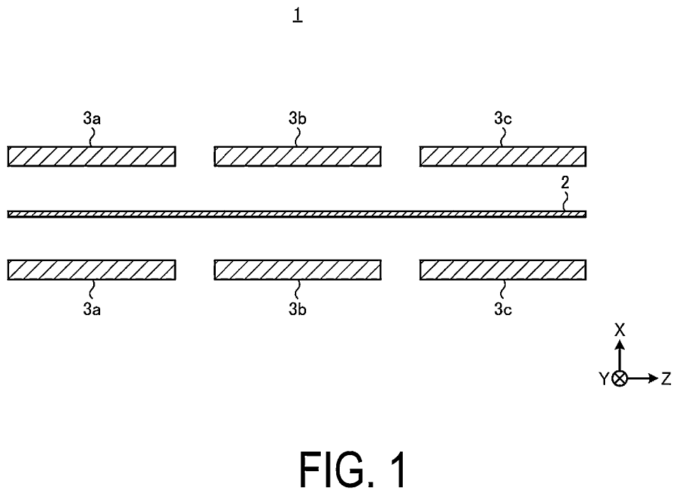

A basic structure of a supply device according to an embodiment will be described with reference to FIG. 1. FIG. 1 is a diagram for describing a basic structure of a supply device according to an embodiment.

FIG. 1 is a cross-sectional view illustrating a basic structure of a supply device 1 according to an embodiment. As illustrated in FIG. 1, the supply device 1 has a coaxial structure. When the coaxial line path is constituted of a center conductor and an external conductor, the supply device 1 includes a signal line 2, an external conductor 3a, an external conductor 3b, and an external conductor 3c. At this time, the potentials of the external conductors each correspond to a reference potential (ground), and a two-dimensional EBG is configured in three dimensions.

An input signal to the supply device 1 flows through the signal line 2. The external conductor 3a, the external conductor 3b, and the external conductor 3c each have a reference potential (ground). The external conductor 3a surrounds the signal line 2. The external conductor 3b surrounds the signal line 2. The external conductor 3c surrounds the signal line 2. There is a gap between the external conductor 3a and the external conductor 3b. There is a gap between the external conductor 3b and the external conductor 3c. That is, the external conductor 3a, the external conductor 3b, and the external conductor 3c are electrically disconnected from each other. In other words, the supply device 1 has a structure in which at least a part of the ground around the signal line 2 is electrically disconnected.

### First Embodiment

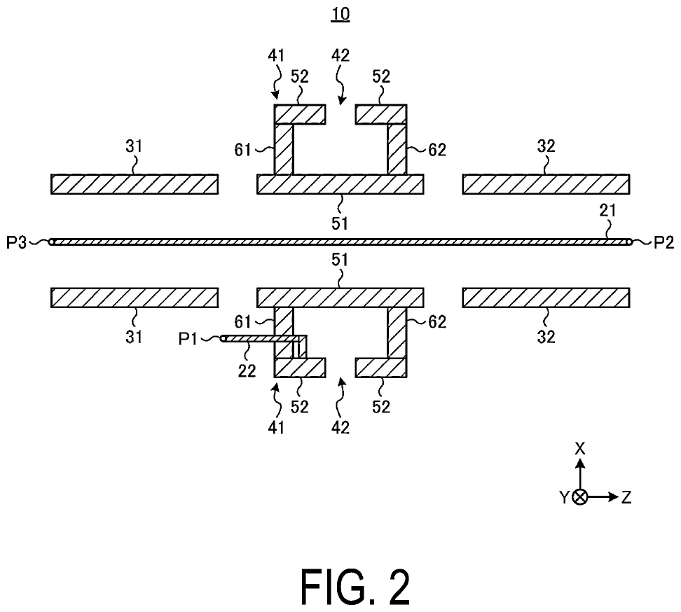

A configuration of the supply device according to the first embodiment will be described with reference to FIG. 2. FIG. 2 is a diagram for describing a configuration example of the supply device according to the first embodiment.

FIG. 2 is a cross-sectional view illustrating a coaxial structure of a supply device 10 according to the first embodiment. As illustrated in FIG. 2, the supply device 10 includes a first signal line 21, a second signal line 22, a first reference line 31, a second reference line 32, and a resonator 41. The first signal line 21, the first reference line 31, and the second reference line 32 may be collectively referred to as a supply target line. The supply target line may have a coaxial structure, for example.

The first signal line 21 is a signal line with a coaxial structure. The second signal line 22 is electrically or magnetically connected to the resonator 41. In other words, the resonator 41 includes the second signal line 22 electrically or magnetically connected to the resonator 41. The supply device 10 includes a first port P1. The first signal line 21 includes a second port P2 and a third port P3. In the first embodiment, a voltage due to a vector potential generated in response to an input signal input to the first port P1 can be generated between the first port P1 and the second port P2. The second signal line 22 may be connected to the resonator 41 at any position thereof. The input impedance may vary depending on a position at which the second signal line 22 is connected to the resonator 41. Any of the first port P1, the second port P2, and the third port P3 may be used as an input port.

Hereinafter, the supply device 10 is described as having a structure including three ports of the first port P1, the second port P2 and the third port P3, but the present disclosure is not limited to this structure. For example, the supply device 10 may have a structure including only two ports of the first port P1 and the second port P2.

The first reference line 31 and the second reference line 32 each have a reference potential (ground). The first reference line 31 surrounds the first signal line 21. The second reference line 32 is located in a different place separated from the first reference line 31. The second reference line 32 surrounds the first signal line 21.

The first reference line 31 and the second reference line 32 may have any shape. For example, the first reference line 31 and the second reference line 32 may have a circular shape, an elliptical shape, and a polygonal shape. The shapes of the first reference line 31 and the second reference line 32 may be different from each other.

The resonator 41 is located between the first reference line 31 and the second reference line 32. The resonator 41 surrounds the first signal line 21. The resonator 41 includes an open portion 42 forming capacitive connection. The resonator 41 has a predetermined resonant frequency. The resonator 41 may also be referred to as an open resonator.

Specifically, the resonator 41 includes a first surrounding conductor 51, a second surrounding conductor 52, a first connection conductor 61, and a second connection conductor 62. The resonator 41 extends along the circumferential direction of the first signal line 21. The resonator 41 may have any shape. The resonator 41 may have a variety of linear shapes. The resonator 41 may have a linear or zigzag shape, for example. The resonator 41 may have a curved shape, for example. The resonator 41 may have a wavy shape, for example. The resonator or a part thereof may be made of a dielectric body or a magnetic body. The resonant frequency of the resonator 41 may vary depending on its shape. In other words, the resonant frequency of the resonator 41 can be adjusted to a desired resonant frequency by adjusting the shape.

The first surrounding conductor 51 surrounds the first signal line 21. The second surrounding conductor 52 is located further away from the first signal line 21 than the first surrounding conductor 51 is. The second surrounding conductor 52 surrounds the first signal line 21. The second surrounding conductor 52 includes the open portion 42 forming capacitive connection.

The first connection conductor 61 and the second connection conductor 62 are each located between the first surrounding conductor 51 and the second surrounding conductor 52. The first connection conductor 61 and the second connection conductor 62 each electrically connect the first surrounding conductor 51 and the second surrounding conductor 52.

### Characteristics of Supply Device

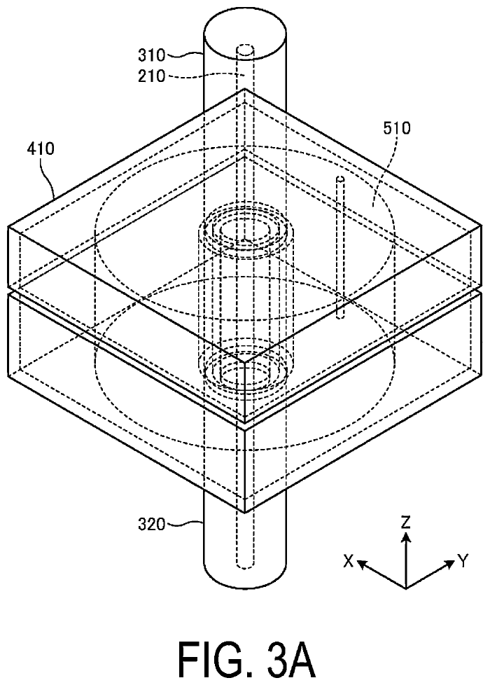

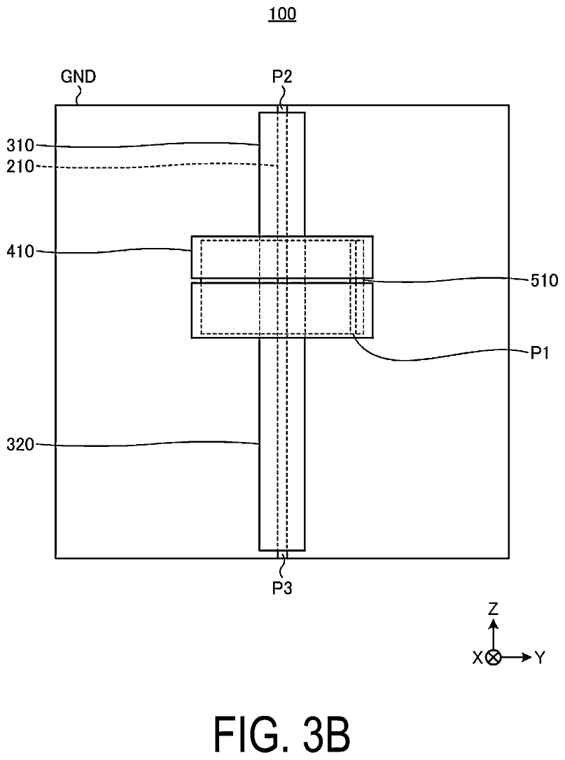

The characteristics of the supply device according to the first embodiment will be described with reference to FIGS. 3A and 3B. FIGS. 3A and 3B are diagrams for describing a simulation model of the supply device according to the first embodiment.

FIGS. 3A and 3B illustrate a supply device model 100 for performing a simulation. The supply device model 100 includes a first signal line 210, a first reference line 310, a second reference line 320, a resonator 410, and a dielectric body 510. The first signal line 210, the first reference line 310, the second reference line 320, and the resonator 410 correspond to the first signal line 21, the first reference line 31, the second reference line 32, and the resonator 41, which are illustrated in FIG. 2, respectively. In FIGS. 3A and 3B, the resonator 410 is described assuming that the open portion therein is linear. Note that the dielectric body 510 is arranged to perform a simulation, and the actual supply device 10 need not include the dielectric body.

As illustrated in FIG. 3B, a state of the magnetic field generated when the input signal is input from the first port P1 is simulated. A quadrilateral surrounding the supply device model 100 indicates a ground (GND). The first reference line 310 and the surrounding ground are electrically disconnected from each other. The second reference line 320 and the surrounding ground are electrically disconnected from each other. Note that in the first embodiment, any of the first port P1, the second port P2, and the third port P3 may be used as an input port.

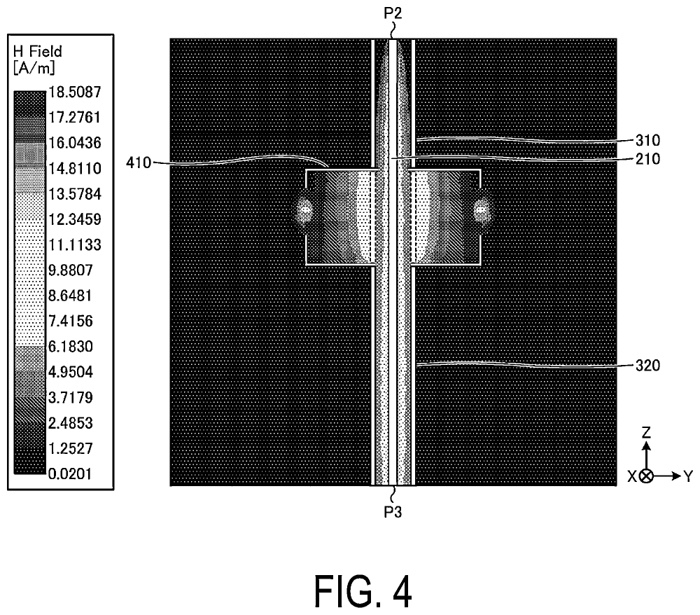

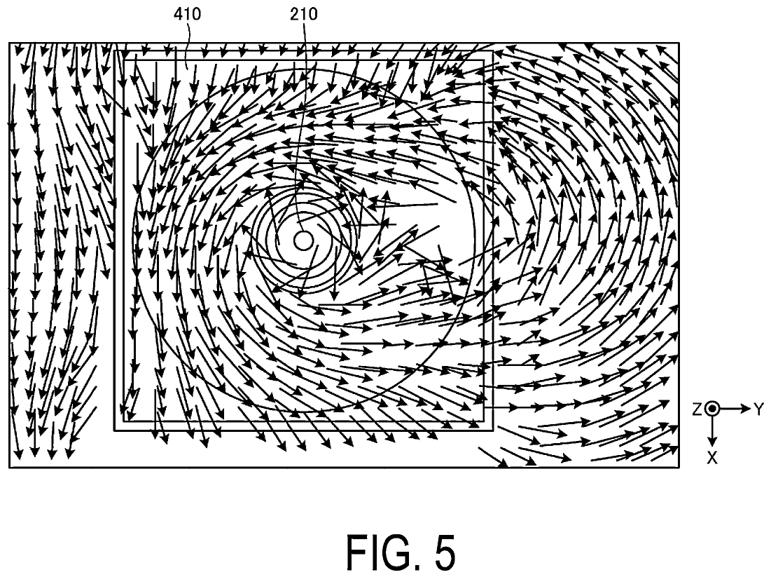

The results of the simulation will be described with reference to FIGS. 4 and 5. FIG. 4 is a diagram for describing a state of the magnetic field distribution of the supply device according to the first embodiment. FIG. 5 is a diagram for describing a state of rotation of the magnetic field of the supply device according to the first embodiment.

FIG. 4 schematically illustrates a cross-section of the supply device model 100. As illustrated in FIG. 4, when an input signal is input from the second port P2 and the input signal flows through the first signal line 210, the magnetic field is generated around and inside the resonator 410. The magnetic field generated around and inside the resonator 410 is stronger as the magnetic field is closer to the first signal line 210 and weaker as the magnetic field is further away from the first signal line 210. The strength of the magnetic field generated around and inside the resonator 410 is, for example, in a range of about 0.02 A/m (Ampere per meter) to 18.51 A/m.

FIG. 5 schematically illustrates a state of the upper portion. In FIG. 5, directions of the magnetic field generated around and inside the resonator 410 are indicated by arrows. As illustrated in FIG. 5, the magnetic field generated around and inside the resonator 410 rotates in the XY plane. Specifically, when the magnetic field rotating around the first signal line 210 with the first signal line 210 as a rotation axis is generated, a linear vector potential in a direction along the first signal line 210 can be generated inside the first signal line 210. Thus, the vector potential is generated in the direction along the first signal line 210, whereby a voltage can be generated between the first port P1 and the second port P2. The voltage generated between the first port P1 and the second port P2 can vary according to the magnitude of the vector potential. The vector potential generated inside the first signal line 210 may vary according to the magnetic field rotating around the first signal line 210. The magnitude of the magnetic field rotating around the first signal line 210 varies according to a current value of an input signal input from the first port P1. Specifically, the voltage generated between the first port P1 and the second port P2 is a value obtained by time differentiation of the current value of the input signal input from the first port P1.

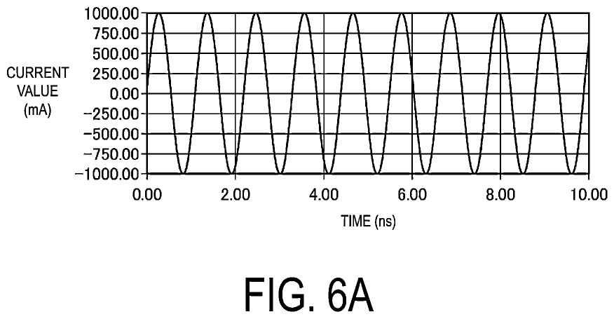

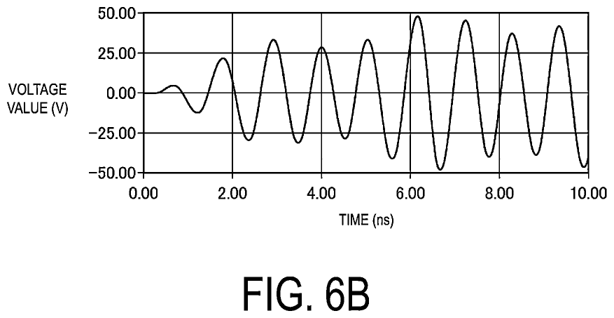

With reference to FIGS. 6A and 6B, the relationship between the input signal input to the first port P1 and the voltage generated between the first port P1 and the second port P2 will be described. FIG. 6A is a graph illustrating the current value of the input signal. FIG. 6B is a graph illustrating the voltage value of the voltage generated by the vector potential.

In FIG. 6A, the horizontal axis represents time (ns (nanosecond)) and the vertical axis represents current value (mA (milliampere)). As illustrated in FIG. 6A, the input signal input to the first port P1 is, for example, an alternating current that varies periodically between −1000 mA and 1000 mA. In FIG. 6B, the horizontal axis represents time (ns) and the vertical axis represents voltage value (V (volt)). As illustrated in FIG. 6B, the voltage generated between the first port P1 and the second port P2 is an alternating voltage that varies periodically between about −50 V and 50 V. As illustrated in FIGS. 6A and 6B, the voltage value is 0 in the vicinity where the current value becomes the maximum value or the minimum value. That is, the voltage generated between the first port P1 and the second port P2 is the value obtained by time differentiation of the current value of the input signal input from the first port P1.

As illustrated in FIGS. 6A and 6B, in the present embodiment, the linear vector potential in the direction along the first signal line 210 can be generated by generating the magnetic field with the first signal line 210 as a rotation axis by the resonator 410.

Specifically, in the present embodiment, by the linear vector potential in the direction along the first signal line 21, a voltage corresponding to the input signal input to the first port P1 can be generated between the first port P1 and the second port P2. That is, according to the present embodiment, power can be transmitted via the resonator 41 in response to an input signal input to the first port P1. Thus, in the present embodiment, by generating the vector potential in the direction along the first signal line 21, the electrical signal and energy can be transmitted without being blocked by an electrically shielding object such as a metal and a magnetic body. That is, the present embodiment can achieve a supply device that can transmit the electrical signal and energy without being blocked by an electrically shielding object such as a metal or a magnetic body.

In the present embodiment, the voltage value corresponding to the input signal input to the first port P1 is determined between the first port P1 and the second port P2. The value of the voltage determined between the first port P1 and the second port P2 may vary depending on the electrical or magnetic properties of the first signal line 210. Here, considering the first signal line 210 as a target conductor, which is a determination target, the value of the voltage determined between the first port P1 and the second port P2 can vary depending on the electrical or magnetic properties of the target conductor. Thus, the present embodiment can achieve a determination device that determines the properties of the target conductor.

That is, the present embodiment can provide a resonator and a determination device that have a novel resonance structure allowing generation of a voltage using a vector potential.

### Variation of First Embodiment

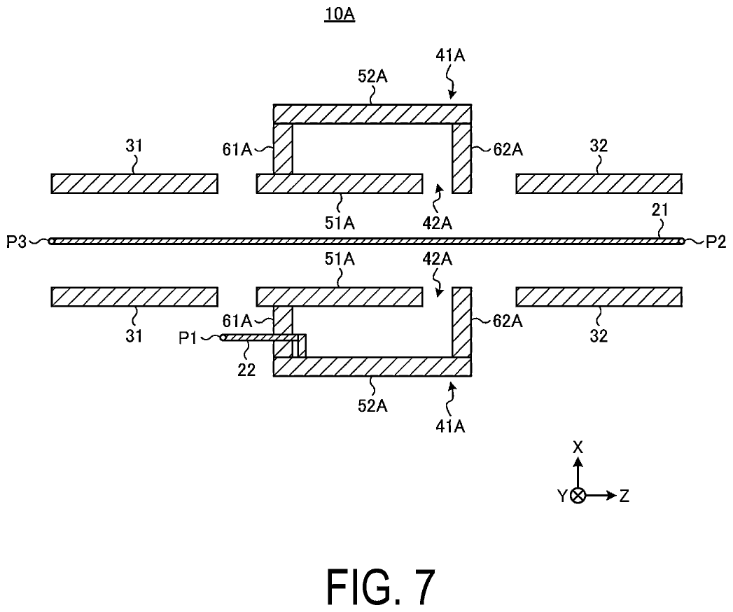

A configuration example of a supply device according to a variation of the first embodiment will be described with reference to FIG. 7. FIG. 7 is a diagram for describing a configuration example of the supply device according to the variation of the first embodiment.

As illustrated in FIG. 7, a supply device 10A includes the first signal line 21, the second signal line 22, the first reference line 31, the second reference line 32, and a resonator 41A. In the supply device 10A, the configuration of the resonator 41A is different from that of the resonator 41 illustrated in FIG. 2.

The resonator 41A includes a first surrounding conductor 51A, a second surrounding conductor 52A, a first connection conductor 61A, and a second connection conductor 62A.

The first surrounding conductor 51A surrounds the first signal line 21. The second surrounding conductor 52A is located further away from the first signal line 21 than the first surrounding conductor 51A is. The second surrounding conductor 52A surrounds the first signal line 21.

The first connection conductor 61A is located between the first surrounding conductor 51A and the second surrounding conductor 52A. The first connection conductor 61A electrically connects the first surrounding conductor 51A and the second surrounding conductor 52A. The second connection conductor 62A is electrically connected to the second surrounding conductor 52A. The first surrounding conductor 51A includes an open portion 42A forming capacitive connection.

That is, the first surrounding conductor may include an open portion forming capacitive connection. An open portion forming capacitive connection may be provided in each of the first surrounding conductor and the second surrounding conductor. That is, as illustrated in the variation of the first embodiment, at least one of the first surrounding conductor and the second surrounding conductor may include an open portion forming capacitive connection.

As described above, in the variation of the first embodiment, at least one of the first surrounding conductor and the second surrounding conductor includes an open portion forming capacitive connection. With such a configuration, in the variation of the first embodiment, a supply device that can transmit the electrical signal and energy can be achieved. In the variation of the first embodiment, a determination device that determines the properties of the target conductor can be achieved. That is, the variation of the first embodiment can provide a resonator and a determination device that have a novel resonance structure allowing generation of a voltage using a vector potential.

### Second Embodiment

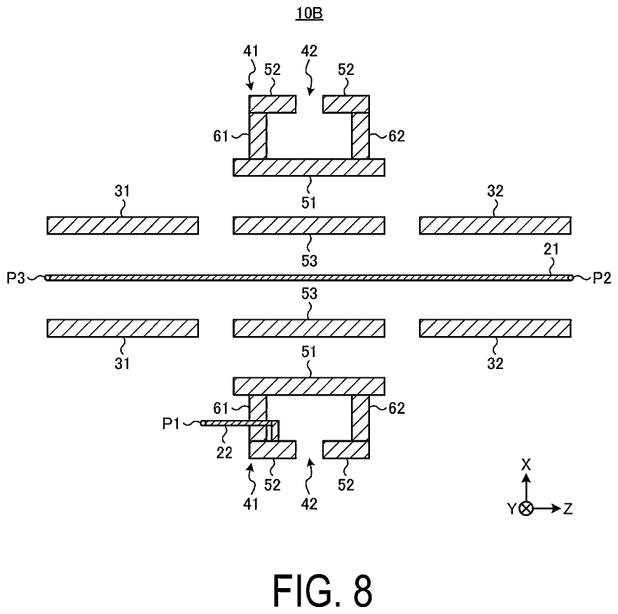

A configuration example of a supply device according to a second embodiment will be described with reference to FIG. 8. FIG. 8 is a diagram for describing a configuration example of the supply device according to the second embodiment.

As illustrated in FIG. 8, a supply device 10B includes the first signal line 21, the second signal line 22, the first reference line 31, the second reference line 32, the resonator 41, and a third surrounding conductor 53. The supply device 10B differs from the supply device 10 illustrated in FIG. 2 in that the supply device 10B includes the third surrounding conductor 53.

A resonator 41 includes the first surrounding conductor 51, the second surrounding conductor 52, the third surrounding conductor 53, the first connection conductor 61, and the second connection conductor 62.

The first surrounding conductor 51, the second surrounding conductor 52, the first connection conductor 61, and the second connection conductor 62 are the same as the first surrounding conductor 51, the second surrounding conductor 52, the first connection conductor 61, and the second connection conductor 62, which are illustrated in FIG. 2, respectively, and thus their descriptions are omitted.

The third surrounding conductor 53 is located between the first signal line 21 and the first surrounding conductor 51. The third surrounding conductor 53 surrounds the first signal line 21.

As described above, in the second embodiment, the third surrounding conductor 53 is located between the first signal line 21 and the resonator 41. In the second embodiment, even with such a configuration, by inputting an input signal from the first port P1, the magnetic field rotating with the first signal line 21 as a rotation axis can be generated inside the resonator 41. Thus, since the vector potential can be generated in the direction along the first signal line 21, the voltage can be generated between the first port P1 and the second port P2 even when a conductor is disposed between the first signal line 21 and the resonator 41.

With such a configuration, in the second embodiment, a supply device that can transmit the electrical signal and energy can be achieved. In the second embodiment, a determination device that determines the properties of the target conductor can be achieved. That is, the present embodiment can provide a resonator and a determination device that have a novel resonance structure allowing generation of a voltage using a vector potential. That is, the second embodiment can provide a resonator and a determination device that have a novel resonance structure allowing generation of a voltage using a vector potential.

### Third Embodiment

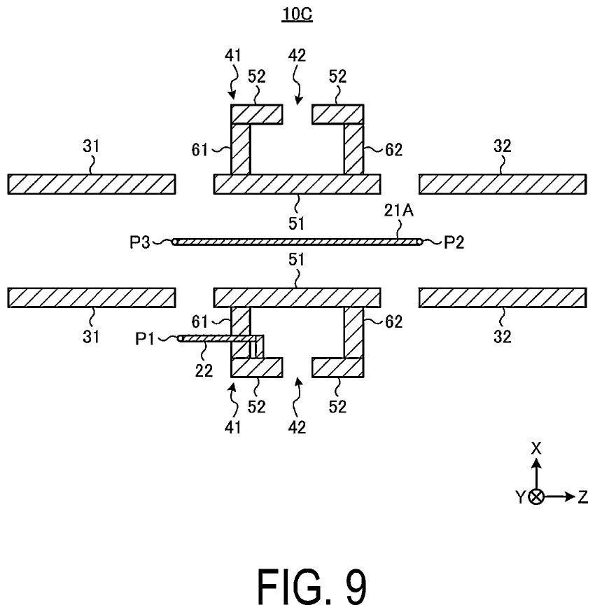

A configuration example of a supply device according to a third embodiment will be described with reference to FIG. 9. FIG. 9 is a diagram for describing a configuration example of the supply device according to the third embodiment.

As illustrated in FIG. 9, a supply device 10C includes a first signal line 21A, the first reference line 31, the second reference line 32, and the resonator 41. The supply device 10C differs from the supply device 10 illustrated in FIG. 2 in the configuration of the first signal line 21A.

The first signal line 21A is electrically shorted at both ends of the resonator 41. Specifically, both ends of the first signal line 21A are connected to signal lines such as a coaxial cable from the outside, at both the ends of the resonator 41.

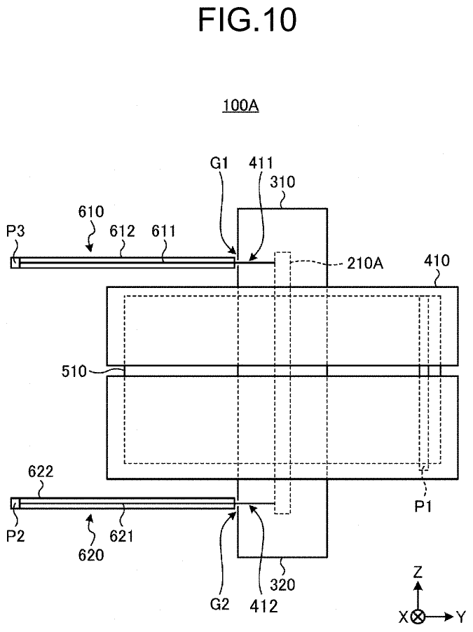

The characteristics of the supply device according to the third embodiment will be described with reference to FIG. 10. FIG. 10 is a diagram for describing a simulation model of the supply device 10C according to the third embodiment.

As illustrated in FIG. 10, a supply device model 100A includes a first signal line 210A, the first reference line 310, the second reference line 320, the resonator 410, the dielectric body 510, a first coaxial line 610, and a second coaxial line 620. The first signal line 210A, the first reference line 310, the second reference line 320, and the resonator 410 correspond to the first signal line 21A, the first reference line 31, the second reference line 32, and the resonator 41, which are illustrated in FIG. 9, respectively.

The first coaxial line 610 and the second coaxial line 620 are connected to the first signal line 210A from the outside.

The first coaxial line 610 includes a signal line 611 and a surrounding conductor 612. The signal line 611 is configured to transmit an electrical signal. The surrounding conductor 612 surrounds the signal line 611. The surrounding conductor 612 has a reference potential (ground). The first coaxial line 610 is externally connected from the first reference line 310 side. Specifically, the first coaxial line 610 is connected from the first reference line 310 side with a gap G1 between the surrounding conductor 612 and the first reference line 310. The gap G1 is, for example, 0.1 mm, but is not limited thereto. That is, the first coaxial line 610 and the first reference line 310 are connected such that the surrounding conductor 612 and the first reference line 310 are electrically disconnected from each other. The first reference line 310 includes a passing hole 411 through which the signal line 611 can pass, at a position to which the first coaxial line 610 is connected. By electrically connecting the signal line 611 to the first signal line 210A through the passing hole 411, the first coaxial line 610 is connected to the first reference line 310 side.

The second coaxial line 620 includes a signal line 621 and a surrounding conductor 622. The signal line 621 is configured to transmit an electrical signal. The surrounding conductor 622 surrounds the signal line 621. The surrounding conductor 622 has a reference potential (ground). The second coaxial line 620 is externally connected from the second reference line 320 side. Specifically, the second coaxial line 620 is connected from the second reference line 320 side with a gap G2 between the surrounding conductor 622 and the second reference line 320. The gap G2 is, for example, 0.1 mm, but is not limited thereto. That is, the second coaxial line 620 and the second reference line 320 are connected such that the surrounding conductor 622 and the second reference line 320 are electrically disconnected from each other. The second reference line 320 includes a passing hole 412 through which the signal line 621 can pass, at a position to which the second coaxial line 620 is connected. By electrically connecting the signal line 621 to the first signal line 210A through the passing hole 412, the second coaxial line 620 is connected to the second reference line 320 side.

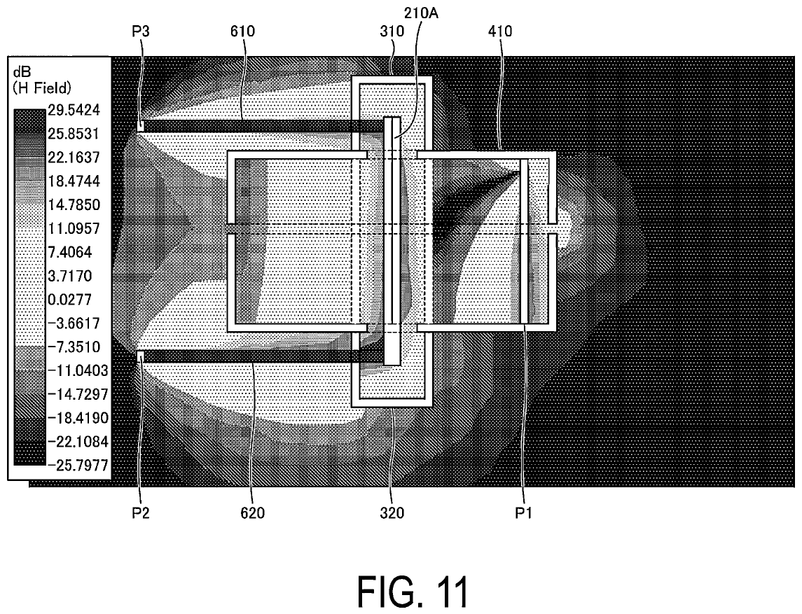

As illustrated in FIG. 11, a state of the magnetic field generated when an input signal is input from the first port P1 is simulated. In the third embodiment, any of the first port P1, the second port P2, and the third port P3 may be used as an input port.

A simulation result will be described with reference to FIG. 11. FIG. 11 is a diagram for describing a state of the magnetic field distribution of the supply device according to the third embodiment. FIG. 11 illustrates a gain (dB (decibel)) of the magnetic field.

As illustrated in FIG. 11, when an input signal flows through the first signal line 210A surrounded by the resonator 410, the magnetic field is generated inside the resonator 410. The magnetic field generated inside the resonator 410 is stronger as the magnetic field is closer to the first signal line 210A and weaker as the magnetic field is further away from the first signal line 210A. The gain of the magnetic field generated around and inside a resonator 410A is, for example, in a range of about −25.80 dB to 29.54 dB. Specifically, when the magnetic field rotating around the first signal line 210A with the first signal line 210A as a rotation axis is generated, a linear vector potential can be generated inside the first signal line 210A. When a vector potential is generated inside the first signal line 210A, a voltage can be generated between the first port P1 and the second port P2. The voltage generated between the first port P1 and the second port P2 varies according to the magnitude of the vector potential generated inside the first signal line 210A.

As illustrated in FIG. 11, the magnetic field is generated around the first coaxial line 610 and the second coaxial line 620. This is the magnetic field generated by the signals passing through the first coaxial line 610 and the second coaxial line 620. That is, in the present embodiment, each port used for input/output or the like need not be provided on a straight line.

With such a configuration, in the third embodiment, a supply device that can transmit the electrical signal and energy can be achieved. In the third embodiment, a determination device that determines the properties of the target conductor can be achieved. That is, the third embodiment can provide a resonator and a determination device that have a novel resonance structure allowing generation of a voltage using a vector potential.

### Other Embodiments

In the first to third embodiments, the supply device 10, the supply device 10A, the supply device 10B, and the supply device 10C are individually used, but the present disclosure is not limited thereto.

For example, the present disclosure may be a configuration in which the supply devices 10 are connected in multiple stages. For example, by electrically connecting any port of the supply device 10 to any port of the other supply device 10, a supply system including a plurality of supply devices 10 may be formed. The same holds true for the supply device 10A, the supply device 10B, and the supply device 10C.

Thus, in other embodiments, with a configuration in which the supply devices are connected in multiple stages, a supply system that can transmit the electrical signal and energy can be achieved. In other embodiments, with a configuration in which determination devices are connected in multiple stages, a determination system that determines the properties of a target conductor can be achieved. That is, other embodiments can provide a resonator and a determination device that have a novel resonance structure allowing generation of a voltage using a vector potential.

The configuration of the present disclosure is not limited to the above-described embodiments, and many variations or changes are possible. For example, the functions included in the respective constituent units can be rearranged so as not to logically contradict each other, and a plurality of constituent units can be combined into one or divided.

1. A supply device comprising:
a resonator and;
a supply target line, wherein
the supply target line comprises:
a first signal line;
a first reference line; and
a second reference line,
the first reference line surrounds the first signal line,
the second reference line is located away from the first reference line and surrounds the first signal line,
the resonator is located between the first reference line and the second reference line and surrounds the first signal line, and
the resonator comprises an open portion forming capacitive connection and comprises a second signal line electrically or magnetically connected to the resonator.

2. The supply device according to claim 1, wherein
the resonator comprises:
a first surrounding conductor; and
a second surrounding conductor,
the first surrounding conductor surrounds the first signal line,
the second surrounding conductor surrounds the first surrounding conductor, and
at least one of the first surrounding conductor and the second surrounding conductor comprises the open portion.

3. The supply device according to claim 2, wherein
the resonator further comprises a third surrounding conductor, and
the third surrounding conductor is located between the first signal line and the first surrounding conductor.

4. The supply device according to claim 1, wherein
the shapes of the first reference line and the second reference line are each any of a circular shape, an elliptical shape, and a polygonal shape.

5. The supply device according to claim 4, wherein the first reference line and the second reference line have different shapes.

6. The supply device according to claim 1, wherein the first signal line is electrically shorted at both ends of the resonator.

7. The supply device according to claim 1, wherein the open portion extends along a circumferential direction.

8. The supply device according to claim 1, wherein the open portion has a linear, wavy, or zigzag shape.

9. The supply device according to claim 1, further comprising a third signal line paired with the second signal line, wherein
the third signal line is connected to a position where matching of an impedance varying according to a contact point of the second signal line is achieved.

10. A determination device comprising:
a resonator;
a first reference line; and
a second reference line, wherein
the first reference line surrounds a target conductor as a determination target,
the second reference line is located away from the first reference line and surrounds the target conductor,
the resonator is located between the first reference line and the second reference line and surrounds the target conductor, and
the resonator comprises an open portion forming capacitive connection and comprises a signal line electrically or magnetically connected to the resonator.
